(19) United States
(12) Patent Application Publication
(10) Pub. No.: US 2025/0051169 A1
(43) Pub. Date: Feb. 13, 2025

(54) Utilization Of Halides To Improve Diamond Properties

(71) Applicant: Massachusetts Institute of Technology, Cambridge, MA (US)

(72) Inventors: Dane William De Quilettes, Somerville, MA (US); Eden C. Price, Boston, MA (US); Justin Lee Mallek, Burlington, MA (US); Jennifer May Schloss, Acton, MA (US); Danielle A. Braje, Winchester, MA (US)

(21) Appl. No.: 18/796,054

(22) Filed: Aug. 6, 2024

Related U.S. Application Data
(60) Provisional application No. 63/517,959, filed on Aug. 7, 2023.

(51) Int. Cl. C01B 32/25; C30B 25/02; C30B 29/04

(52) U.S. Cl. CPC C01B 32/25; C30B 25/02; C30B 29/04; C01P 2002/90

(57) ABSTRACT

Described herein is a diamond and diamond products comprising:
a NV⁰ or SiV⁰ defect, wherein the NV⁰ or SiV⁰ defect comprises a nitrogen atom or silicon atom replacing a carbon atom in the diamond and a neutral vacancy replacing a carbon atom adjacent to the nitrogen atom or silicon atom in the diamond;
a NV⁻ or SiV⁻ defect, wherein the NV⁻ or SiV⁻ defect comprises a nitrogen atom or silicon atom replacing a carbon atom in the diamond and a negatively-charged vacancy replacing a carbon atom adjacent to the nitrogen atom or silicon atom in the diamond; and
a halide atom.

### RELATED APPLICATION(S)

This application claims the benefit of U.S. Provisional Application No. 63/517,959 filed on Aug. 7, 2023. The entire teachings of the above application(s) are incorporated herein by reference.

### GOVERNMENT SUPPORT

This invention was made with government support under Grant Number FA8702-15-D-0001 awarded by the U.S. Air Force. The government has certain rights in the invention.

### BACKGROUND

The growth and processing of advanced diamond materials has become increasingly popular due to the ability to tailor diamond properties for quantum information science. For example, structural defects in diamond offer promising qubit platforms for quantum computing. In biology, for example, diamond's biocompatibility makes it ideal for detecting minute biological changes as biological sensors. Additionally, diamond has been used in industrial abrasives, high-performance optical windows, and luxury jewelry due to its hardness and optical properties.

### SUMMARY

In one aspect disclosed herein is a diamond comprising,
a) a NV⁰ or SiV⁰ defect, wherein the NV⁰ or SiV⁰ defect comprises a nitrogen atom or silicon atom replacing a carbon atom in the diamond and a neutral vacancy replacing a carbon atom adjacent to the nitrogen atom or silicon atom in the diamond;
b) a NV⁻ or SiV⁻ defect, wherein the NV⁻ or SiV⁻ defect comprises a nitrogen atom or silicon atom replacing a carbon atom in the diamond and a negatively-charged vacancy replacing a carbon atom adjacent to the nitrogen atom or silicon atom in the diamond; and
c) a halide atom.

In one embodiment of the disclosed diamond, the diamond comprises the NV⁰ defect, the NV⁻ defect, and the halide atom.

In one embodiment of the disclosed diamond, the concentration of nitrogen atoms in the diamond is from about 1 ppm to about 10 ppm.

In one embodiment of the disclosed diamond, the diamond is a diamond layer having a thickness of from about 1 μm to about 50 μm.

In one embodiment of the disclosed diamond, the diamond is a diamond layer having a thickness of about 40 μm, and wherein the halide atom is at a depth of from about 0 μm to about 2 μm from a surface of the diamond.

In one embodiment of the disclosed diamond, the halide atom is chlorine.

In one embodiment of the disclosed diamond, the concentration of halide atoms in the diamond is from about 1×10¹⁵ atoms per cm³ to about 1×10¹⁷ atoms per cm³.

In another aspect of the disclosure herein is a quantum device comprising a diamond, the diamond comprising:
a) a NV⁰ or SiV⁰ defect, wherein the NV⁰ or SiV⁰ defect comprises a nitrogen atom or silicon atom replacing a carbon atom in the diamond and a neutral vacancy replacing a carbon atom adjacent to the nitrogen atom or silicon atom in the diamond;
b) a NV⁻ or SiV⁻ defect, wherein the NV⁻ or SiV⁻ defect comprises a nitrogen atom or silicon atom replacing a carbon atom in the diamond and a negatively-charged vacancy replacing a carbon atom adjacent to the nitrogen atom or silicon atom in the diamond; and
c) a halide atom.

In one embodiment of the disclosed quantum device, the quantum device is a quantum computer or quantum sensor.

In another aspect of the disclosure herein is a method of forming a diamond layer, the method comprising:
a) growing a non-doped diamond layer having an as-grown growth face on a substrate, implanting a halide atom and an N or Si atom into the as-grown growth face of the non-doped diamond layer to produce a halide-doped diamond layer comprising a NV⁰ or SiV⁰ defect, and annealing the halide-doped diamond layer to form a NV⁻ or SiV⁻ defect from the NV⁰ or SiV⁰ defect;
b) growing an N-doped or Si-doped diamond layer having an as-grown growth face on a substrate using a dopant gas comprising a nitrogen or silicon source wherein the N-doped or Si-doped diamond layer comprises a NV⁰ or SiV⁰ defect, implanting a halide atom into the as-grown growth face of the N-doped or Si-doped diamond layer to produce a halide-doped diamond layer, and annealing the halide-doped diamond layer to form a NV⁻ or SiV⁻ defect from the NV⁰ or SiV⁰ defect; or
c) growing a halide-doped diamond layer having an as-grown growth face on a substrate using a dopant gas comprising a nitrogen or silicon source and a halide precursor wherein the halide-doped diamond layer comprises a NV⁰ or SiV⁰ defect and a halide atom, and annealing the halide-doped diamond layer to form a NV⁻ or SiV⁻ defect from the NV⁰ or SiV⁰ defect,
wherein the diamond layer comprises:
   a. the NV⁰ or SiV⁰ defect, wherein the NV⁰ or SiV⁰ defect comprises a nitrogen atom or silicon atom replacing a carbon atom in the diamond and a neutral vacancy replacing a carbon atom adjacent to the nitrogen atom or silicon atom in the diamond;
   b. the NV⁻ or SiV⁻ defect, wherein the NV⁻ or SiV⁻ defect comprises a nitrogen atom or silicon atom replacing a carbon atom in the diamond and a negatively-charged vacancy replacing a carbon atom adjacent to the nitrogen atom or silicon atom in the diamond; and
   c. the halide atom.

In one embodiment of the disclosed method, the method further comprises removing the substrate from the halide-doped diamond layer.

In one embodiment of the disclosed method, the annealing in a), b), or c) is performed using ultra-high vacuum annealing at a temperature of from about 800° C. to about 1200° C.

In one embodiment of the disclosed method, the dopant gas in b) or c) comprises N₂, N₂O, Si(OC₂H₅)₄ or SiF₄.

In one embodiment of the disclosed method, the implanting the halide atom in a) or b) comprises using an implant dose of from about 1×10¹⁰ atoms/cm² to about 1×10¹⁵ atoms/cm².

In one embodiment of the disclosed method, the implanting the halide atom in a) or b) comprises using an implant energy of from about 1 MeV to about 5 MeV.

In one embodiment of the disclosed method, the halide precursor is titanium (IV) chloride, carbon tetrabromide, vanadium (V) trichloride oxide, boron bromide, 3-aminopropyltriethoxysilane, or hafnium tetrachloride.

In one embodiment of the disclosed method, the halide atom is chlorine.

In one embodiment of the disclosed method, the growing in a), b), or c) comprises using a high-pressure high-temperature (HPHT) or a chemical vapor deposition (CVD) technique.

In one embodiment of the disclosed method, the chemical vapor deposition technique is plasma enhanced chemical vapor deposition (PE-CVD).

In one embodiment of the disclosed method, the plasma enhanced chemical vapor deposition (PE-CVD) comprises injecting methane and hydrogen gas into a chamber to reach a pressure of about 100 torr to about 200 torr.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, including those illustrated in the drawings interspersed herein. The drawings are not necessarily to scale, emphasis instead being placed upon illustrating embodiments.

FIG. 1 shows an example comparison between engineered quantum systems and traditional quantum systems.

FIG. 2 shows example advantages of solid-state quantum devices.

FIG. 3 shows an example comparison between a trapped ion system and diamond with integrated photonics.

FIG. 4 shows example properties of diamond with nitrogen vacancy centers.

FIG. 5 shows example sources of diamond, such as mined diamonds, diamonds produced by high-pressure high-temperature (HPHT), and chemical vapor deposition (CVD).

FIG. 6 shows a process of diamond growth and processing, according to an embodiment.

FIG. 7 schematically shows an example multi-donor doping strategy using both nitrogen and phosphorus as dopants which lowers the activation energy of NV-formation. Some embodiments of the present invention employ similar multi-donor doping techniques.

FIG. 8A is a schematic illustration of the growth of a 40 μm-thick ¹²C buffer layer on a substrate used in embodiment simulations.

FIG. 8B is a graph and schematic showing the number of ¹⁵N atoms per cm³ of diamond layer at an implant dose of 1×10¹² atoms/cm² simulated using Stopping Range of Ions Motion (SRIM) software. The implant energy for N is 2 MeV. Embodiments utilize a range of such implant dose and implant energy.

FIG. 9A is a graph of the number of ¹⁵N and ¹⁷Cl atoms per cm³ of diamond layer at an implant dose of 5×10¹¹ atoms/cm² for the ¹⁷Cl atoms and an implant dose of 1×10¹² atoms/cm² for the ¹⁵N atoms using SRIM software in an example embodiment. The implant energy for Cl and N is 3 MeV and 2 MeV respectively. The concentration per depth of the atoms places representation of ¹⁵N atoms to the right hand side of that of ¹⁷Cl atoms on the graph.

FIG. 9B is a graph of the number of ¹⁵N and ¹⁷Cl atoms per cm³ of diamond layer at an implant dose of 1×10¹² atoms/cm² for the ¹⁷Cl and ¹⁵N atoms using SRIM software in an example embodiment. The implant energy for Cl and N is 3 MeV and 2 MeV respectively. The concentration per depth of the atoms places representation of ¹⁵N atoms to the right hand side of that of ¹⁷Cl atoms on the graph.

FIG. 9C is a graph of the number of ¹⁵N and ¹⁷Cl atoms per cm³ of diamond layer at an implant dose of 3×10¹² atoms/cm² for the ¹⁷Cl atoms and an implant dose of 1×10¹² atoms/cm² for the ¹⁵N atoms using SRIM software in an example embodiment. The implant energy for Cl and N is 3 MeV and 2 MeV respectively. The concentration per depth of the atoms places representation of ¹⁵N atoms to the right hand side of that of ¹⁷Cl atoms on the graph.

FIG. 9D is a schematic view of ¹⁷Cl (top layer) and ¹⁵N (embedded layer) implantation as in some embodiments.

FIG. 10A is a confocal photoluminescence (PL) as a function of increasing dose for chlorine (Cl), oxygen (O) and lithium (Li). PL intensity is shown on a color scale (right) from 0 to 1 and is due to neutral vacancy. FIG. 10A shows PL intensity before annealing in an example embodiment while FIGS. 11A-11C show PL intensity after annealing which activates defects and more desired V-type defects (negative charge vacancies) formed at higher implant doses.

FIG. 10B is a graph of the vacancy signal as a function of implant dose in units of 10¹² atoms/cm² normalized to the Li signal. The difference between the measured vacancies compared to expected values is due to vacancy species other than V°.

FIG. 11A shows PL intensity after annealing as a function of increasing dose for chlorine (Cl), oxygen (O) and lithium (Li) dopants in the example embodiment. PL intensity is due to neutral vacancy (neutral NV⁰ defects). Dosage is given for 5×10¹¹, 1×10¹², and 3×10¹² atoms/cm².

FIG. 11B shows PL intensity after annealing as a function of increasing dose for chlorine (Cl), oxygen (O) and lithium (Li) dopants in the example embodiment. PL intensity is due to negatively charged NV⁻ defects.

FIG. 11C shows PL intensity after annealing as a function of increasing dose for chlorine (Cl), oxygen (O) and lithium (Li) dopants in the example embodiment. PL intensity is due to negatively charged SiV⁻ defects.

FIG. 12 is a graph of Applicant's NV⁰ and NV⁻ yield from a) nitrogen and lithium, b) nitrogen and oxygen, and c) nitrogen and chlorine implantation, versus nitrogen only without lithium, oxygen, or chlorine implantation. Also shown are vacancies from Stopping and Range of Ions in Matter (SRIM) simulations and the implant dose. Multi-dopants including Cl lead to eight times as many NV⁻ (negative charged vacancies) compared to the control sample (far left on the graph).

### DETAILED DESCRIPTION

A description of example embodiments follows.

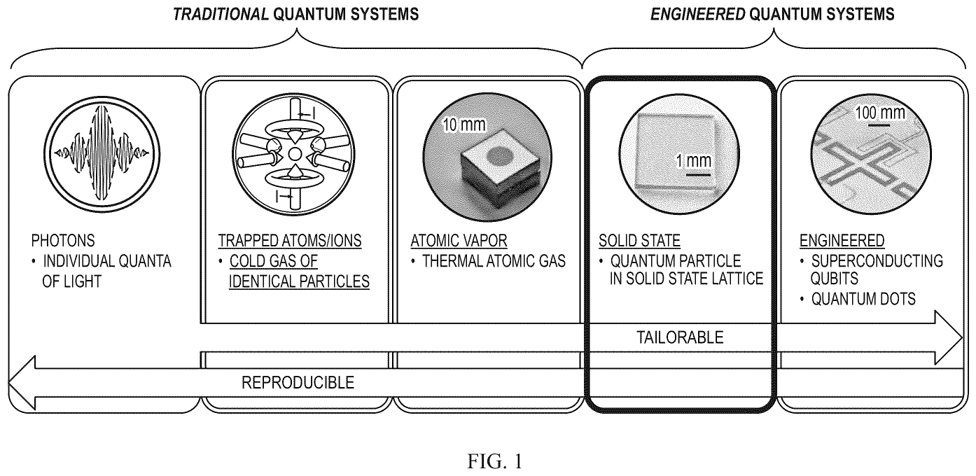

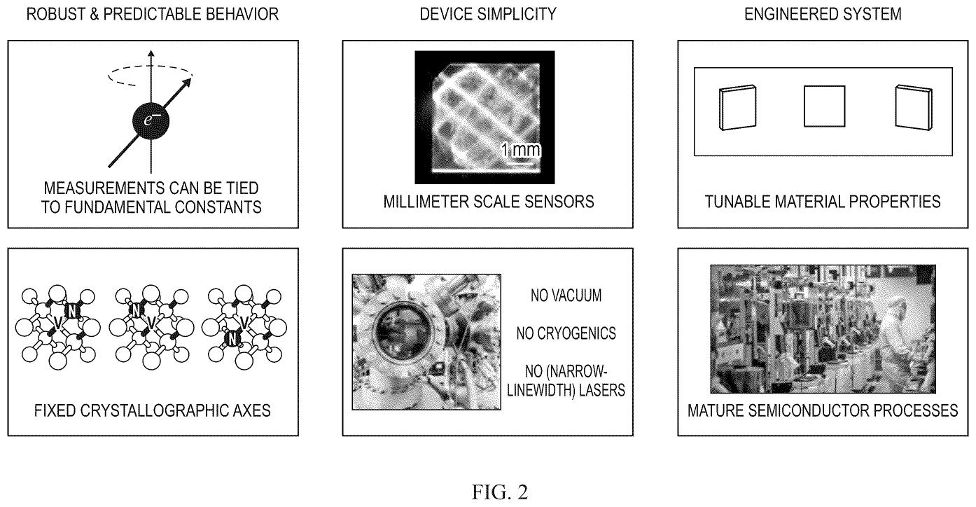

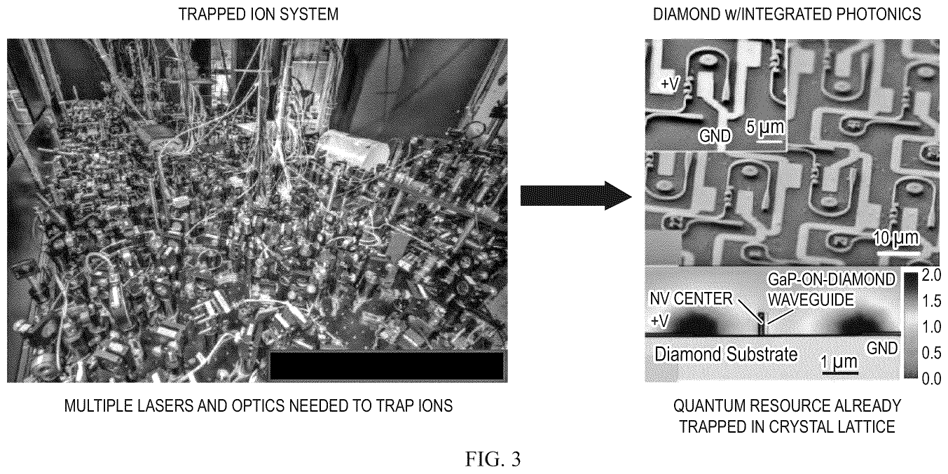

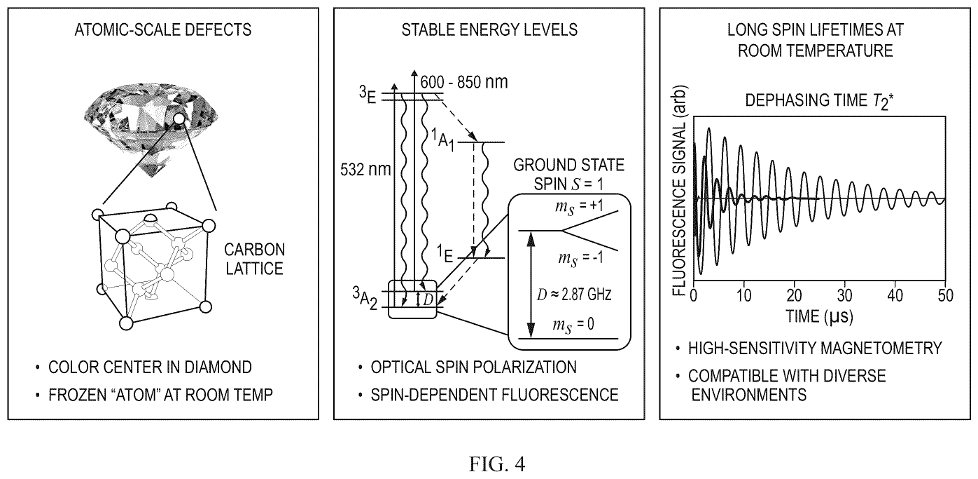

In some embodiments, the disclosure herein can be categorized in the general area of advanced materials growth and processing of diamond for applications in quantum information science and technology (such as in engineered quantum systems, FIG. 1), biological sensors, abrasives, jewelry, optical windows, and other diamond-based applications. Diamonds of the present disclosure may be incorporated in solid state quantum devices. These devices may possess, for example, fixed crystallographic axes, tunable properties, and measurements can be tied to fundamental constants (FIG. 2). As opposed to trapped ion systems where multiple lasers and optics are needed to trap ions, diamonds can be integrated with photonics where the quantum resource (e.g., nitrogen vacancy defects) is already trapped in the diamond crystal lattice (FIG. 3). For example, in quantum computing, the nitrogen vacancy (NV) centers can act as single qubits, where quantum information is stored in the spin states of the NV center. Diamond-incorporated quantum devices possess advantages over trapped ion systems, such as a more than three-fold reduction of scale, computability with nanofabrication, excellent photon interface, and ability to work at visible frequencies. As shown in FIG. 4, diamond vacancy centers such as NV centers are atomic-scale defects with stable energy levels and long spin lifetimes at room temperature.

In some embodiments, this disclosure refers to a process of using a halide (fluorine, chlorine, bromine, or iodine) during the growth or processing of diamond to increase the crystal quality or performance of diamond. For example, such processes include growing in or implanting a halide to control the growth kinetics, defect incorporation, defect density, defect charge state, and/or any other mechanical, electronic, magnetic, or optical property of the resulting diamond. In addition, inclusion of halides may also improve diamond mechanical properties such as hardness, electronic properties such as conductivity, and magnetic properties such as spin coherence. The direct impact of incorporating halides includes significantly enhanced defect-based qubits in diamond for quantum sensing, communication, computing, and simulations. The direct impact also includes better quality diamond for gemstone purposes.

Others have used halogens to create precursors that are then used to form the diamond without incorporating halides into the diamond or fluorinate a diamond surface to diamond film coatings for improved cutting tools, lenses/windows, biological implants [see references 7-13]. Large halide elements, such as Cl or Br, would be expected to introduce strain and other types of unwanted defects and, therefore, have not been previously pursued.

There are several performance and economic advantages of incorporating a halide into diamond. For example, one potential use of this technology would be in the field of quantum information. One of the largest issues facing the feasibility of quantum devices that rely on solid-state qubits, such as quantum grade diamond, is low impurity-vacancy center (NV, SiV, SnV) yield. While electron irradiation may be used to displace carbon atoms to create vacancy centers and annealing may be used to mobilize vacancies to create high yields of NV⁻ centers, there exists a careful balance between total electron irradiation dose and substitutional nitrogen content. At high electron irradiation doses, N-to-NV conversion decreases [14]. The improved performance that halide incorporation could provide includes, for example, improved charge state stability, charge conversion efficiency, coherence time, or crystal quality. Improved creation of desired defects will improve the performance of diamond in qubits, quantum emitters, and quantum sensors. For example, higher NV⁻ creation yield leads to improved magnetometer sensitivity in quantum sensing applications.

There have been other attempts to implant donor species into quantum diamond [see references 7-13]. However, these gases are often toxic, expensive, and not always highly available.

Compared to some donors like sulfur and phosphorus, halide precursors (e.g., titanium (IV) chloride, carbon tetrabromide, vanadium (V) trichloride oxide, boron bromide, 3-Aminopropyltriethoxysilane, hafnium tetrachloride) are less toxic than the hydrides typically used in the manufacturing of semiconductors. These “toxic metal hydrides” often used in the semiconductor industry have very specific guidelines for handling them. For example, phosphorus-doping is a common technique for diamond [1], and phosphine gas has an OSHA exposure limit of 0.3 ppm over 10 hours (Department of Labor, Phosphine, https_www_osha_gov/chemicaldata/667). However, carbon tetrachloride, a halide precursor, has an OSHA exposure limit of 10 ppm over 8 hours (Department of Labor, Carbon Tetrachloride, https_www_osha_gov/chemicaldata/844). Furthermore, the handling of these toxic metal hydrides such as phosphine often requires breathing apparatuses, while halogenated compounds like carbon tetrachloride only typically require standard chemical personal protective equipment [2]. In terms of availability, halides are some of the more common elements in organic gas species and there are plenty of options of types of precursors that contain the halide.

In other fields, such as jewelry, there are several advantages of using halide incorporation over using alternate methods to improve diamond quality. For example, lab-grown diamond quality can be poor with crystallographic defects grown in, such as unwanted color centers, unepitaxial crystals, flattop hillocks, and pyramidal hillocks. Attempts to overcome this include controlling the diamond seed layer properties, the growth recipe, and post-processing such as polishing or HPHT (high pressure high temperature). Controlling the miscut angle of diamond can be costly. Therefore, a method of minimizing unwanted defects such as hillocks that does not rely on controlling the miscut angle allows more diamond seeds to be used.

The present disclosure generally relates to a diamond comprising a substitutional defect (e.g., nitrogen-containing defect or a silicon-containing defect), and a halide atom. As defined herein, a substitutional defect is one where a host atom (e.g., carbon) is replaced by another element. Examples of a nitrogen-containing defect include nitrogen-vacancy defects (NₙV, where the number of nitrogen atoms n ranges from 1 to 4), nitrogen-vacancy-hydrogen defects (NₙVH, where n=1-3), and di-nitrogen vacancy defects (such as N₃V₂N). Examples of a silicon-containing defect include silicon-vacancy defects (SiV), silicon di-vacancy defects (SiV₂), silicon-vacancy-hydrogen defects (SiVH), and silicon di-vacancy hydrogen defects (SiV₂H).

The nitrogen vacancy center, NV, comprises a single substitutional N atom adjacent to a vacant lattice site, giving the defect a trigonal C₃ᵥ symmetry. Three charge states of NV are known, +, 0, and −, with total ground-state spin S=0, ½, and 1, respectively. For example, NV⁰ represents an NV defect of charge 0 (also referred to herein as neutral). NV⁺ represents an NV defect of positive charge. NV⁻ represents an NV defect of negative charge.

In some embodiments, a diamond (e.g., diamond layer) comprises:
a) a NV⁰ or SiV⁰ defect, wherein the NV⁰ or SiV⁰ defect comprises a nitrogen atom or silicon atom replacing a carbon atom in the diamond and a neutral vacancy replacing a carbon atom adjacent to the nitrogen atom or silicon atom in the diamond;
b) a NV⁻ or SiV⁻ defect, wherein the NV⁻ or SiV⁻ defect comprises a nitrogen atom or silicon atom replacing a carbon atom in the diamond and a negatively-charged vacancy replacing a carbon atom adjacent to the nitrogen atom or silicon atom in the diamond; and
c) a halide atom.

In some embodiments, a diamond comprises a NV⁰ defect, a NV⁻ defect, and a halide atom.

In some embodiments, a diamond comprises a diamond layer. In some embodiments, a diamond consists essentially of a diamond layer. In some embodiments, a diamond consists of a diamond layer. In some embodiments, a diamond is a diamond layer.

In some embodiments, the concentration of nitrogen atoms in a diamond is from about 0.1 ppm to about 100 ppm (e.g., about 0.1 ppm to about 70 ppm, about 0.1 ppm to about 50 ppm, about 0.1 ppm to about 40 ppm, about 0.1 ppm to about 30 ppm, about 0.1 ppm to about 20 ppm, about 0.1 ppm to about 10 ppm, about 1 ppm to about 10 ppm, about 1 ppm to about 5 ppm, about 5 ppm to 10 ppm, etc.). In some embodiments, the concentration of nitrogen atoms in a diamond is from about 1 ppm to about 10 ppm.

In some embodiments, a diamond of the present disclosure further comprises a surface, wherein at least a portion of said surface is formed of as-grown growth face diamond material. In some embodiments, as-grown growth face diamond material has not been polished or etched.

In some embodiments, a diamond comprises a diamond layer having a thickness of from about 0.1 μm to about 1000 μm (e.g., about 0.1 μm to about 900 μm, about 0.1 μm to about 800 μm, about 0.1 μm to about 700 μm, about 0.1 μm to about 600 μm, about 0.1 μm to about 500 μm, about 0.1 μm to about 400 μm, about 0.1 μm to about 300 μm, about 0.1 μm to about 200 μm, about 0.1 μm to about 100 μm, about 0.1 μm to about 50 μm, about 1 μm to about 500 μm, about 1 μm to about 50 μm, about 1 μm to about 40 μm, about 1 μm to about 30 μm, about 1 μm to about 20 μm, about 1 μm to about 10 μm, etc.). In some embodiments, a diamond comprises a diamond layer having a thickness of from about 1 μm to about 500 μm. In some embodiments, a diamond comprises a diamond layer having a thickness of from about 1 μm to about 50 μm.

In some embodiments, a diamond is a diamond layer having a thickness of from about 0.1 μm to about 1000 μm (e.g., about 0.1 μm to about 900 μm, about 0.1 μm to about 800 μm, about 0.1 μm to about 700 μm, about 0.1 μm to about 600 μm, about 0.1 μm to about 500 μm, about 0.1 μm to about 400 μm, about 0.1 μm to about 300 μm, about 0.1 μm to about 200 μm, about 0.1 μm to about 100 μm, about 0.1 μm to about 50 μm, about 1 μm to about 500 μm, about 1 μm to about 50 μm, about 1 μm to about 40 μm, about 1 μm to about 30 μm, about 1 μm to about 20 μm, about 1 μm to about 10 μm, etc.). In some embodiments, a diamond is a diamond layer having a thickness of from about 1 μm to about 500 μm. In some embodiments, a diamond is a diamond layer having a thickness of from about 1 μm to about 50 μm.

In some embodiments, a diamond may have at least one lateral dimension of at least 0.5 mm, 1 mm. 2 mm, 3 mm. 4 mm, 4.5 mm, or 5 mm. In some embodiments, a diamond may have at least one lateral dimension of from about 0.1 mm to about 10 cm. In some embodiments, a diamond may have at least one lateral dimension of from about 1 mm to about 1 cm.

As used herein. “as-grown growth face” of a diamond refers to a surface or a face of a diamond crystal that is formed during a growth process. For example, a diamond grown under high-pressure high-temperature (HPHT) conditions may have an as-grown growth face with an orientation (e.g., Miller indices) of {100}, {111}, {110}, {112}, or a combination thereof. In another example, a diamond grown using chemical vapor deposition (CVD) may have an as-grown growth face with an orientation (e.g., Miller indices) of {111}, {100}, {110}, or a combination thereof. In some embodiments, a surface of a diamond is an as-grown growth face or a portion thereof. In some embodiments, a surface of a diamond is an as-grown growth face.

In some embodiments, a nitrogen atom is at a depth of from about 0 μm to about 50 μm (e.g., about 0 μm to about 10 μm, about 0 μm to about 9 μm, about 0 μm to about 8 μm, about 0 μm to about 7 μm, about 0 μm to about 6 μm, about 0 μm to about 5 μm, about 0 μm to about 4 μm, about 0 μm to about 3 μm, about 0 μm to about 2 μm, about 1 μm to about 2 μm, about 1.4 μm to about 2 μm, about 1.5 μm to about 2 μm, etc.) from a surface (e.g., an as-grown growth face or a portion thereof) of a diamond. In some embodiments, a nitrogen atom is at a depth of from about 0 μm to about 2 μm from a surface of a diamond. In some embodiments, a nitrogen atom is at a depth of from about 1 μm to about 2 μm from a surface of a diamond. In some embodiments, a diamond is a diamond layer having a thickness of about 40 μm, and wherein a nitrogen atom is at a depth of from about 1 μm to about 2 μm from a surface of a diamond. In some embodiments, a diamond is a diamond layer having a thickness of about 40 μm, and wherein a nitrogen atom is at a depth of from about 1.4 μm to about 2 μm from a surface of a diamond.

In some embodiments, a halide atom is at a depth of from about 0 μm to about 50 μm (e.g., about 0 μm to about 10 μm, about 0 μm to about 9 μm, about 0 μm to about 8 μm, about 0 μm to about 7 μm, about 0 μm to about 6 μm, about 0 μm to about 5 μm, about 0 μm to about 4 μm, about 0 μm to about 3 μm, about 0 μm to about 2 μm, about 0 μm to about 1 μm, about 0.5 μm to about 1 μm, etc.) from a surface (e.g., an as-grown growth face or a portion thereof) of a diamond. In some embodiments, a halide atom is at a depth of from about 0 μm to about 2 μm from a surface of a diamond. In some embodiments, a halide atom is at a depth of from about 0.5 μm to about 1 μm from a surface of a diamond. In some embodiments, a diamond is a diamond layer having a thickness of about 40 μm, and wherein a halide atom is at a depth of from about 0 μm to about 2 μm from a surface of a diamond. In some embodiments, a diamond is a diamond layer having a thickness of about 40 μm, and wherein a halide atom is at a depth of from about 0.5 μm to about 1 μm from a surface of a diamond.

In some embodiments, a halide atom is fluorine, chlorine, bromine, or iodine. In some embodiments, a halide atom is chlorine.

In some embodiments, the concentration of halide atoms in a diamond is from about 1×10¹² atoms per cm³ to about 1×10¹⁸ atoms per cm³ (e.g., about 1×10¹³ atoms per cm³ to about 1×10¹⁸ atoms per cm³, about 1×10¹⁴ atoms per cm³ to about 1×10¹⁸ atoms per cm³, about 1×10¹⁵ atoms per cm³ to about 1×10¹⁸ atoms per cm³, about 1×10¹⁵ atoms per cm³ to about 9×10¹⁷ atoms per cm³, about 1×10¹⁵ atoms per cm³ to about 8×10¹⁷ atoms per cm³, about 1×10¹⁵ atoms per cm³ to about 7×10¹⁷ atoms per cm³, about 1×10¹⁵ atoms per cm³ to about 6×10¹⁷ atoms per cm³, about 1×10¹⁵ atoms per cm³ to about 5×10¹⁷ atoms per cm³, about 1×10¹⁵ atoms per cm³ to about 4×10¹⁷ atoms per cm³, about 1×10¹⁵ atoms per cm³ to about 3×10¹⁷ atoms per cm³, about 1×10¹⁵ atoms per cm³ to about 2×10¹⁷ atoms per cm³, about 1×10¹⁵ atoms per cm³ to about 1×10¹⁶ atoms per cm³, etc.). In some embodiments, the concentration of halide atoms in a diamond is from about 1×10¹⁵ atoms per cm³ to about 1×10¹⁷ atoms per cm³.

As defined herein, surface roughness Rₐ refers to the arithmetic mean of the absolute deviation of surface profile from the mean line measured. In some embodiments, surface roughness Rₐ of at least a portion of an as-grown growth face of a diamond (e.g., a diamond layer) is equal to or smaller than about 80 nm. 50 nm, 20 nm, 10 nm, 5 nm, 2 nm. 1 nm, or 0.5 nm. In some embodiments, the surface roughness Rₐ of at least a portion of an as-grown growth face is from about 0 nm to about 80 nm (e.g., about 0 nm to about 70 nm, about 0 nm to about 60 nm, about 0 nm to about 50 nm, about 0 nm to about 40 nm, about 0 nm to about 30 nm, about 0 nm to about 20 nm, about 0 nm to about 10 nm, about 0 nm to about 5 nm, about 0 nm to about 2 nm, about 0 nm to about 1 nm, about 0 nm to about 0.5 nm, etc.).

In some embodiments, diamonds of the present disclosure are used for imaging, sensing, or quantum information processing.

In some embodiments, diamonds of the present disclosure may further comprise structural features which have nano-scale dimensions, e.g. nano-rings, nano-channels (e.g. microfluidics), nano-beams or nano-pillars patterned on a larger substrate. For example, these features may be overgrown with another layer of diamond material, that is, a further diamond layer may be grown over the as-grown growth face after implanting nitrogen.

### Quantum Devices

The present disclosure also relates to quantum devices comprising a diamond, the diamond comprising:
a) a NV⁰ or SiV⁰ defect, wherein the NV⁰ or SiV⁰ defect comprises a nitrogen atom or silicon atom replacing a carbon atom in the diamond and a neutral vacancy replacing a carbon atom adjacent to the nitrogen atom or silicon atom in the diamond;
b) a NV⁻ or SiV⁻ defect, wherein the NV⁻ or SiV⁻ defect comprises a nitrogen atom or silicon atom replacing a carbon atom in the diamond and a negatively-charged vacancy replacing a carbon atom adjacent to the nitrogen atom or silicon atom in the diamond; and
c) a halide atom.

In some embodiments, quantum devices of the present disclosure further comprise a light source (e.g., a laser). In some embodiments, a light source is configured to an appropriate wavelength (e.g., 532 nm, 594 nm, 637 nm, 738 nm) to excite a defect (e.g., a NV or SiV⁻ defect) in a diamond of a quantum device. In some embodiments, the light source is configured to a wavelength of 532 nm to excite a NV⁻ defect. In other embodiments, the light source is configured to a wavelength of 738 nm to excite a SiV defect.

Upon excitation, a defect may be optically pumped into its excited state. For example, to excite the NV⁻ center electronically, a light source may be used to promote an electron from the ³A ground state to the ³E excited state. Once in the excited state, the NV center may decay back to the ground state, emitting a photon.

NV⁻ or SiV⁻ centers can emit photons upon optical excitation, making them reliable photon sources and attractive for use in quantum communication protocols, such as quantum key distribution (QKD). Entanglement between NV⁻ or SiV⁻ centers and photons may aid in quantum networks and quantum teleportation applications.

In some embodiments, a light source is a laser.

In some embodiments, a quantum device is a quantum photonic device.

In some embodiments, a quantum device (e.g., a quantum photonic device) is a quantum computer or quantum sensor.

### Methods

The present disclosure also relates to methods of forming a diamond layer, comprising:
a) growing a non-doped diamond layer having an as-grown growth face on a substrate, implanting a halide atom and an N or Si atom into the as-grown growth face of the non-doped diamond layer to produce a halide-doped diamond layer comprising a NV⁰ or SiV⁰ defect, and annealing the halide-doped diamond layer to form a NV⁻ or SiV⁻ defect from the NV⁰ or SiV⁰ defect;
b) growing an N-doped or Si-doped diamond layer having an as-grown growth face on a substrate using a dopant gas comprising a nitrogen or silicon source wherein the N-doped or Si-doped diamond layer comprises a NV⁰ or SiV⁰ defect, implanting a halide atom into the as-grown growth face of the N-doped or Si-doped diamond layer to produce a halide-doped diamond layer, and annealing the halide-doped diamond layer to form a NV⁻ or SiV⁻ defect from the NV⁰ or SiV⁰ defect; or
c) growing a halide-doped diamond layer having an as-grown growth face on a substrate using a dopant gas comprising a nitrogen or silicon source and a halide precursor wherein the halide-doped diamond layer comprises a NV⁰ or SiV⁰ defect and a halide atom, and annealing the halide-doped diamond layer to form a NV⁻ or SiV⁻ defect from the NV⁰ or SiV⁰ defect.

In some embodiments, methods of forming a diamond layer comprise:
a) growing a non-doped diamond layer having an as-grown growth face on a substrate, implanting a halide atom and an N or Si atom into the as-grown growth face of the non-doped diamond layer to produce a halide-doped diamond layer comprising a NV⁰ or SiV⁰ defect, and annealing the halide-doped diamond layer to form a NV⁻ or SiV⁻ defect from the NV⁰ or SiV⁰ defect;
b) growing an N-doped or Si-doped diamond layer having an as-grown growth face on a substrate using a dopant gas comprising a nitrogen or silicon source wherein the N-doped or Si-doped diamond layer comprises a NV⁰ or SiV⁰ defect, implanting a halide atom into the as-grown growth face of the N-doped or Si-doped diamond layer to produce a halide-doped diamond layer, and annealing the halide-doped diamond layer to form a NV⁻ or SiV⁻ defect from the NV⁰ or SiV⁰ defect; or
c) growing a halide-doped diamond layer having an as-grown growth face on a substrate using a dopant gas comprising a nitrogen or silicon source and a halide precursor wherein the halide-doped diamond layer comprises a NV⁰ or SiV⁰ defect and a halide atom, and annealing the halide-doped diamond layer to form a NV⁻ or SiV⁻ defect from the NV⁰ or SiV⁰ defect,
   wherein the diamond layer comprises:
1. the NV⁰ or SiV⁰ defect, wherein the NV⁰ or SiV⁰ defect comprises a nitrogen atom or silicon atom replacing a carbon atom in the diamond and a neutral vacancy replacing a carbon atom adjacent to the nitrogen atom or silicon atom in the diamond;
2. the NV⁻ or SiV⁻ defect, wherein the NV⁻ or SiV⁻ defect comprises a nitrogen atom or silicon atom replacing a carbon atom in the diamond and a negatively-charged vacancy replacing a carbon atom adjacent to the nitrogen atom or silicon atom in the diamond; and
3. the halide atom.

In some embodiments, methods of forming a diamond layer comprise growing a non-doped diamond layer having an as-grown growth face on a substrate, implanting a halide atom and an N or Si atom into the as-grown growth face of the non-doped diamond layer to produce a halide-doped diamond layer comprising a NV⁰ or SiV⁰ defect, and annealing the halide-doped diamond layer to form a NV⁻ or SiV⁻ defect from the NV⁰ or SiV⁰ defect. In some embodiments, methods of forming a diamond layer comprise growing a non-doped diamond layer having an as-grown growth face on a substrate, implanting a halide atom and an N atom into the as-grown growth face of the non-doped diamond layer to produce a halide-doped diamond layer comprising a NV⁰ defect, and annealing the halide-doped diamond layer to form a NV⁻ defect from the NV⁰ defect.

In some embodiments, methods of forming a diamond layer comprise growing an N-doped or Si-doped diamond layer having an as-grown growth face on a substrate using a dopant gas comprising a nitrogen or silicon source wherein the N-doped or Si-doped diamond layer comprises a NV⁰ or SiV⁰ defect, implanting a halide atom into the as-grown growth face of the N-doped or Si-doped diamond layer to produce a halide-doped diamond layer, and annealing the halide-doped diamond layer to form a NV⁻ or SiV⁻ defect from the NV⁰ or SiV⁰ defect. In some embodiments, methods of forming a diamond layer comprise growing an N-doped diamond layer having an as-grown growth face on a substrate using a dopant gas comprising a nitrogen source wherein the N-doped diamond layer comprises a NV⁰ defect, implanting a halide atom into the as-grown growth face of the N-doped diamond layer to produce a halide-doped diamond layer, and annealing the halide-doped diamond layer to form a NV⁻ defect from the NV⁰ defect.

In some embodiments, methods of forming a diamond layer comprise growing a halide-doped diamond layer having an as-grown growth face on a substrate using a dopant gas comprising a nitrogen or silicon source and a halide precursor wherein the halide-doped diamond layer comprises a NV⁰ or SiV⁰ defect and a halide atom, and annealing the halide-doped diamond layer to form a NV⁻ or SiV⁻ defect from the NV⁰ or SiV⁰ defect. In some embodiments, methods of forming a diamond layer comprise growing a halide-doped diamond layer having an as-grown growth face on a substrate using a dopant gas comprising a nitrogen source and a halide precursor wherein the halide-doped diamond layer comprises a NV⁰ defect and a halide atom, and annealing the halide-doped diamond layer to form a NV⁻ defect from the NV⁰ defect.

After diamond growth, a diamond layer may be removed from a substrate, for example, by cutting and/or mechanical processing. Polishing methods know in the art, such as scaife or chemical mechanical polishing, may be carefully controlled to prepare a substrate for diamond growth while minimizing the level of subsurface damage introduced during processing. The surface of a substrate may be etched in-situ immediately prior to diamond growth thereon. In some embodiments, methods of the present disclosure further comprise removing the substrate from a halide-doped diamond layer.

In some embodiments, annealing a halide-doped diamond layer to form a NV⁻ or SiV⁻ defect from a NV⁰ or SiV⁰ defect is performed using a heat treatment technique (e.g., low pressure high temperature (LPHT) and high pressure high temperature (HPHT), ultra-high vacuum annealing, etc.). In some embodiments, annealing a halide-doped diamond layer to form a NV⁻ or SiV⁻ defect from a NV⁰ or SiV⁰ defect is performed using ultra-high vacuum annealing.

In some embodiments, annealing a halide-doped diamond layer to form a NV⁻ or SiV⁻ defect from a NV⁰ or SiV⁰ defect is performed at a temperature of from about 400° C. to about 2000° C. (e.g., about 400° C. to about 1900° C., about 400° C. to about 1800° C., about 400° C. to about 1700° C., about 400° C. to about 1600° C., about 400° C. to about 1500° C., about 400° C. to about 1400° C., about 400° C. to about 1300° C., about 400° C. to about 1200° C., about 500° C. to about 1100° C., about 600° C. to about 1200° C., about 600° C. to about 1000° C., about 800° C. to about 1200° C., etc.). In some embodiments, annealing a halide-doped diamond layer to form a NV⁻ or SiV⁻ defect from a NV⁰ or SiV⁰ defect is performed using ultra-high vacuum annealing at a temperature of about 1000° C.

In some embodiments, annealing a halide-doped diamond layer to form a NV⁻ or SiV⁻ defect from a NV⁰ or SiV⁰ defect is performed at a pressure of from about 10⁻⁶ Pa to about 10⁻¹⁰ Pa (e.g., about 10⁻⁷ Pa to about 10⁻¹⁰ Pa, about 10⁻⁷ Pa to about 10⁻⁹ Pa, about 10⁻⁷ Pa to about 10⁻⁸ Pa, etc.). In some embodiments, annealing a halide-doped diamond layer to form a NV⁻ or SiV⁻ defect from a NV⁰ or SiV⁰ defect is performed at a pressure of about 10⁻⁸ Pa.

In some embodiments, annealing a halide-doped diamond layer to form a NV⁻ or SiV⁻ defect from a NV⁰ or SiV⁰ defect is performed for at least 10 minutes (e.g., 1 hour, 2 hours, 4 hours, 6 hours, 8 hours, etc.).

Annealing may be performed in one or more steps. For example, annealing may be performed step-wise at different temperatures. e.g. a first anneal at a first temperature and a second anneal at a second temperature which is different from the first temperature (higher or lower). In some embodiments, a first anneal is performed at from about 500° C. to about 2000° C. and a second anneal is performed at from about 500° C. to about 2000° C. In some embodiments, a first anneal is performed at about 1400° C. and a second anneal is performed at about 1000° C.

Annealing may be performed at a temperature which is sufficiently high to repair crystallographic defects/damage but sufficiently low such that impurity-vacancy defects are not broken up. For example, a first anneal may be performed at a temperature sufficient to promote formation of impurity-vacancy quantum spin defects and then a second anneal may be performed at a relatively higher temperature which repairs crystallographic defects/damage while not being so high as to break up the impurity-vacancy defects. In some embodiments, a first anneal is performed at about 800° C. and a second anneal is performed at about 1100° C. for non-limiting example.

In some embodiments, a dopant gas comprises a nitrogen source (e.g., N₂, N₂O) or a silicon source (e.g., Si(OC₂H₅)₄ and SiF₄). Examples of a dopant gas include N₂, N₂O, Si(OC₂H₅)₄ and SiF₄. In some embodiments, a dopant gas comprises N₂, N₂O, Si(OC₂H₅)₄ or SiF₄. In some embodiments, a dopant gas comprises N₂, N₂O, or SiF₄. In some embodiments, a dopant gas comprises N₂ or N₂O. In some embodiments, a dopant gas is N₂, N₂O, or SiF₄. In some embodiments, a dopant gas is N₂ or N₂O.

In some embodiments, implanting a halide atom comprises using an implant dose of from about 1×10¹⁰ atoms/cm² to about 1×10¹⁵ atoms/cm² (e.g., about 1×10¹⁰ atoms/cm² to about 1×10¹⁴ atoms/cm², 1×10¹¹ atoms/cm² to about 1×10¹⁴ atoms/cm², 1×10¹¹ atoms/cm² to about 1×10¹³ atoms/cm², 5×10¹¹ atoms/cm² to about 5×10¹² atoms/cm², etc.). In some embodiments, implanting a halide atom comprises using an implant dose of from about 5×10¹¹ atoms/cm² to about 5×10¹² atoms/cm². In some embodiments, implanting a halide atom into an as-grown growth face of a non-doped diamond layer, N-doped diamond layer, or Si-doped diamond layer comprises using an implant dose of from about 1×10¹⁰ atoms/cm² to about 1×10¹⁵ atoms/cm². In some embodiments, implanting a halide atom into an as-grown growth face of a non-doped diamond layer, N-doped diamond layer, or Si-doped diamond layer comprises using an implant dose of from about 1×10¹⁰ atoms/cm² to about 1×10¹⁵ atoms/cm² (e.g., about 1×10¹⁰ atoms/cm² to about 1×10¹⁴ atoms/cm², 1×10¹¹ atoms/cm² to about 1×10¹⁴ atoms/cm², 1×10¹¹ atoms/cm² to about 1×10¹³ atoms/cm², 5×10¹¹ atoms/cm² to about 5×10¹² atoms/cm², etc.). In some embodiments, implanting a halide atom into an as-grown growth face of a non-doped diamond layer, N-doped diamond layer, or Si-doped diamond layer comprises using an implant dose of from about 5×10¹¹ atoms/cm² to about 5×10¹² atoms/cm².

In some embodiments, implanting a nitrogen atom comprises using an implant energy of from about 1 MeV to about 10 MeV (e.g., about 1 MeV to about 5 MeV, about 1 MeV to about 4 MeV, about 1 MeV to about 3 MeV, etc.). In some embodiments, implanting a nitrogen atom into an as-grown growth face of a non-doped diamond layer comprises using an implant energy of from about 1 MeV to about 10 MeV (e.g., about 1 MeV to about 5 MeV, about 1 MeV to about 4 MeV, about 1 MeV to about 3 MeV, etc.). In some embodiments, implanting a nitrogen atom into an as-grown growth face of a non-doped diamond layer comprises using an implant energy of about 2 MeV.

In some embodiments, implanting a halide atom comprises using an implant energy of from about 1 MeV to about 10 MeV (e.g., about 1 MeV to about 5 MeV, about 1 MeV to about 4 MeV, about 1 MeV to about 3 MeV, etc.). In some embodiments, implanting a halide atom comprises using an implant energy of from about 1 MeV to about 5 MeV. In some embodiments, implanting a halide atom into an as-grown growth face of a non-doped diamond layer, N-doped diamond layer, or Si-doped diamond layer comprises using an implant energy of from about 1 MeV to about 10 MeV (e.g., about 1 MeV to about 5 MeV, about 1 MeV to about 4 MeV, about 1 MeV to about 3 MeV, etc.). In some embodiments, implanting a halide atom into an as-grown growth face of a non-doped diamond layer, N-doped diamond layer, or Si-doped diamond layer comprises using an implant energy of from about 1 MeV to about 5 MeV. In some embodiments, implanting a halide atom into the as-grown growth face of a non-doped diamond layer, N-doped diamond layer, or Si-doped diamond layer comprises using an implant energy of about 3 MeV.

In some embodiments, a halide precursor is titanium (IV) chloride, carbon tetrabromide, vanadium (V) trichloride oxide, boron bromide, 3-aminopropyltriethoxysilane, or hafnium tetrachloride.

In some embodiments, a halide atom is chlorine.

In some embodiments, a) growing a non-doped diamond layer having an as-grown growth face on a substrate, b) growing an N-doped or Si-doped diamond layer having an as-grown growth face on a substrate using a dopant gas comprising a nitrogen or silicon source, or c) growing a halide-doped diamond layer having an as-grown growth face on a substrate using a dopant gas comprising a nitrogen or silicon source and a halide precursor comprises using a high-pressure high temperature (HPHT) or a chemical vapor deposition (CVD) technique. In some embodiments, the chemical vapor deposition technique is plasma enhanced chemical vapor deposition (PE-CVD).

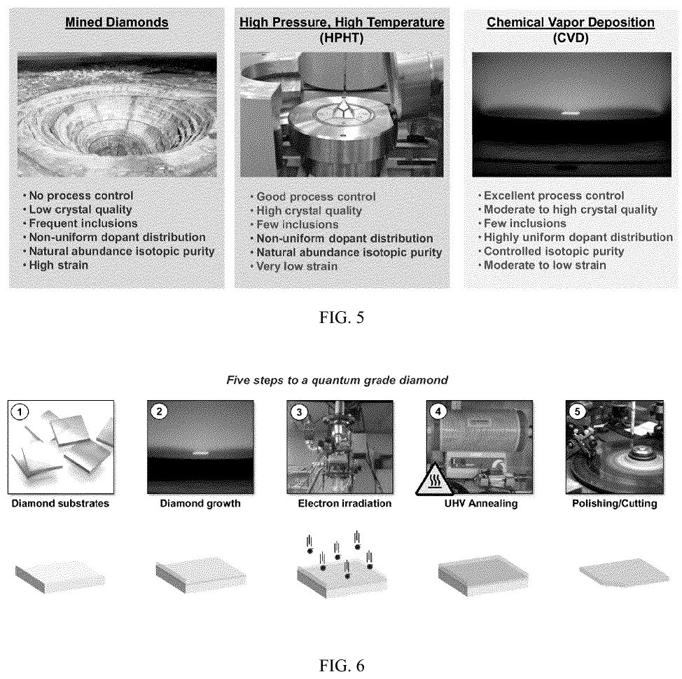

As shown in FIG. 5, diamonds produced from both HPHT and CVD techniques present advantages over mined diamonds, such as high crystal quality and low strain. Diamonds grown using CVD possess highly uniform dopant distribution and controlled isotopic purity.

An example process of a quantum-grade diamond growth and processing, according to an embodiment, is shown in FIG. 6. For example, in an embodiment, a diamond layer doped with nitrogen is grown on a substrate using CVD, followed by electron irradiation to create vacancies within the diamond layer, ultra-high vacuum annealing, and polishing/cutting to remove the diamond layer from the substrate.

In some embodiments, plasma enhanced chemical vapor deposition (PE-CVD) comprises injecting methane and hydrogen gas into a chamber. In some embodiments, plasma enhanced chemical vapor deposition (PE-CVD) comprises injecting methane and hydrogen gas into a chamber to reach a pressure of from about 50 torr to about 200 torr (e.g., about 50 torr to about 190 torr, about 50 torr to about 180 torr, about 50 torr to about 170 torr, about 50 torr to about 160 torr, about 50 torr to about 150 torr, about 60 torr to about 150 torr, about 100 torr to about 200 torr, etc.). In some embodiments, plasma enhanced chemical vapor deposition (PE-CVD) comprises injecting methane and hydrogen gas into a chamber to reach a pressure of from about 100 torr to about 200 torr. In some embodiments, plasma enhanced chemical vapor deposition (PE-CVD) comprises injecting methane and hydrogen gas into a chamber to reach a pressure of about 100 torr.

In order to incorporate a halide in any form into a diamond, one may produce diamonds in which one could introduce a halide into the diamond structure using diamond processing and fabrication techniques, for example, a high-pressure high temperature (HPHT) technique or any chemical vapor deposition (PE-CVD) including hot filament and plasma-enhanced. Incorporating a halide into a diamond may be performed using a solid state, liquid, or gaseous precursor. For example, a diamond may be grown with a halide precursor flowing in the reactor chamber in gaseous form to be incorporated during growth. Alternatively, an ion beam may be used to implant the diamond with a halide. All types of diamond processing and halide incorporation are contemplated herein, for example, growth through PE-CVD or HPHT, post growth processing such as implantation, or other forms of diamond fabrication.

In order for the diamond quality to benefit from the presence of the halide, the halide may need to be “activated”. The activation of the halide may be in-situ while processing the diamond may be part of the post-processing step. For example, if the goal is to produce defects for quantum purposes, the sample may be annealed to activate halide and vacancy defects. Before annealing, most vacancies formed may be either in neutral vacancy (V⁰) or negatively charged vacancy (V⁻), but after annealing, these negatively charged vacancies can freely move and pair with defects such as NV or SiV to become desirable defects like NV⁻ and SiV⁻.

Contemplated herein is the usage of any halide to improve the quality or performance of diamond. The halide-doped diamond may be used for quantum information science and technology, biological sensors, semiconductor doping, abrasives, jewelry, optical windows, or any alternative diamond-based applications. The incorporation of a halide into a diamond may improve any mechanical, electronic, magnetic, optical, or defect related property of the diamond prior to incorporation. For example, a halide (e.g., chlorine) may be implanted into quantum grade diamond using a low energy (<100 kV) or high energy (>1 MV) ion implant beam at a density comparable to the quantum defect of interest such as SiV⁻ and NV⁻. These defects are the basis for many areas of quantum technology and therefore an increased yield of these defects measured through photoluminescence measurements indicates improved performance of the diamond.

Disclosed herein is the increase in performance of diamond through halide ion implantation. For example, chlorine has been shown to increase the yield of both NV⁻ and SiV⁻ color centers compared to standard control diamond samples. These color centers are used for quantum technologies such as quantum sensing and quantum communication.

Contemplated herein are various means to measure performance improvement in diamond, including but not limited to mechanical, electronic, optical, and magnetic properties. These improvements can be measured through a range of techniques, for example, photoluminescence (PL), coherence time measurements, crystallographic strain measurements, Fourier-Transform Infrared measurements (FTIR), Electron paramagnetic resonance (EPR), and/or Ultraviolet-Visible spectroscopy (UV-Vis).

It should be understood that the subject matter defined in the appended claims is not necessarily limited to the specific implementations described above. The description and drawings herein are for purposes of illustration and not limitation of the principals of the present invention. The specific implementations described above are disclosed as non-limiting examples only.

### Definitions

It is to be understood that the terminology used herein is for describing particular embodiments only and is not intended to be limiting. Unless defined otherwise, all technical and scientific terms used herein have the same meaning as commonly understood by one of ordinary skill in the art to which the disclosure pertains.

Although any methods and materials similar or equivalent to those described herein may be used in the practice for testing of the present disclosure, exemplary materials and methods are described herein.

When a list is presented, unless stated otherwise, it is to be understood that each individual element of that list, and every combination of that list, is a separate embodiment. For example, a list of embodiments presented as “A, B, or C” is to be interpreted as including the embodiments, “A,” “B,” “C,” “A or B,” “A or C,” “B or C,” or “A, B, or C.”

As used in this specification and the appended claims, the singular forms “a,” “an,” and “the” include plural referents unless the content clearly dictates otherwise. The conjunctive term “and/or” between multiple recited elements is understood as encompassing both individual and combined options. For instance, where two elements are conjoined by “and/or,” a first option refers to the applicability of the first element without the second. A second option refers to the applicability of the second element without the first. A third option refers to the applicability of the first and second elements together. Any one of these options is understood to fall within the meaning, and therefore satisfy the requirement of the term “and/or” as used herein. Concurrent applicability of more than one of the options is also understood to fall within the meaning, and therefore satisfy the requirement of the term “and/or.”

Unless the context requires otherwise, throughout the specification and claims that follow, the word “comprise” and synonyms and variants thereof such as “have” and “include”, as well as variations thereof, such as “comprises” and “comprising”, are to be construed in an open, inclusive sense, e.g., “including, but not limited to.” The transitional terms “comprising,” “consisting essentially of,” and “consisting of” are intended to connote their generally accepted meanings in the patent vernacular; that is, (i) “comprising,” which is synonymous with “including,” “containing,” or “characterized by,” is inclusive or open-ended and does not exclude additional, unrecited elements or method steps; (ii) “consisting of” excludes any element or step not specified in the claim; and (iii) “consisting essentially of” limits the scope of a claim to the specified materials or steps “and those that do not materially affect the basic and novel characteristic(s)” of the claimed disclosure and disclosure. Embodiments described in terms of the phrase “comprising” (or its equivalents) also provide as embodiments those independently described in terms of “consisting of” and “consisting essentially of.”

“About” means within an acceptable error range for the particular value as determined by one of ordinary skill in the art, which will depend in part on how the value is measured or determined, i.e., the limitations of the measurement system. Unless explicitly stated otherwise within the disclosure, claims, result or embodiment, “about” means within one standard deviation per the practice in the art, or can mean a range of ±20%, ±10%, ±5%, ±4, ±3, ±2 or ±1% of a given value. It is to be understood that the term “about” can precede any particular value specified herein, except for particular values used in the Examples.

All percents are intended to be weight percent unless otherwise specified. The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

Those skilled in the art will recognize, or be able to ascertain, using no more than routine experimentation, numerous equivalents to the specific substances and procedures described herein. Such equivalents are intended to be encompassed in the scope of the claims that follow the examples below.

### EXAMPLES

### Example 1

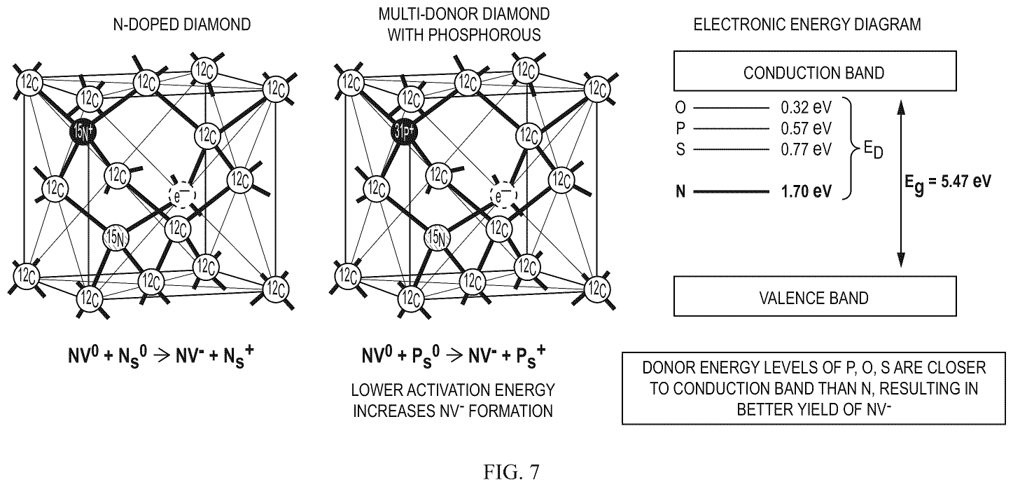

Multi-donor doping strategies are disclosed in addressing N-doped diamond challenges. As shown in FIG. 7, in a multi-donor diamond, for example, phosphorus lowers the activation energy required to create the NV⁻ centers and increases NV⁻ formation. The donor energy levels of phosphorus, as well as other elements including oxygen and sulfur, are closer to the conduction band than nitrogen, resulting in better yield of NV⁻.

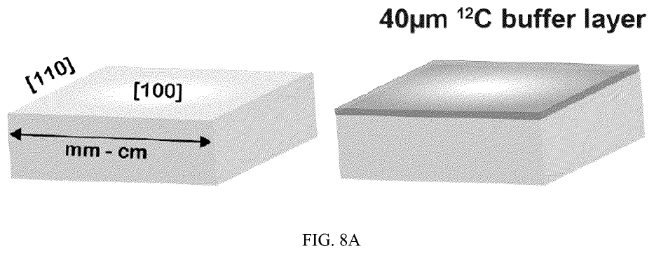

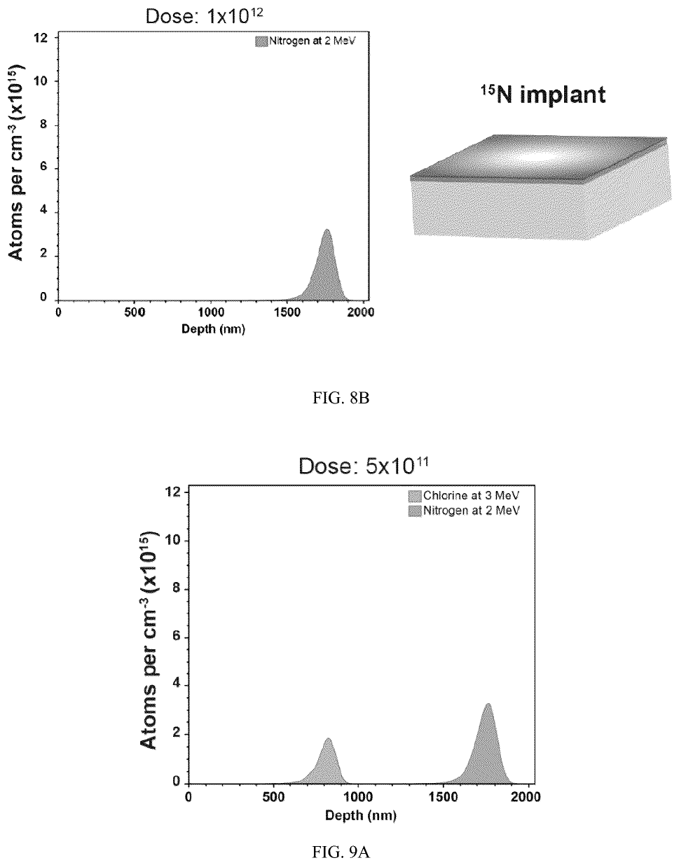

Simulations of nitrogen and/or chlorine implantation on a 40 μm-thick ¹²C buffer layer (FIG. 8A) were conducted using Stopping Range of Ions Motion (SRIM) software. At an implant dose of 1×10¹² atoms/cm² and implant energy of 2 MeV, most of the nitrogen atoms were distributed at a depth of between 1400 nm and 1900 nm, with concentrations up to about 4×10¹⁵ nitrogen atoms per cm³. FIG. 8B is illustrative.

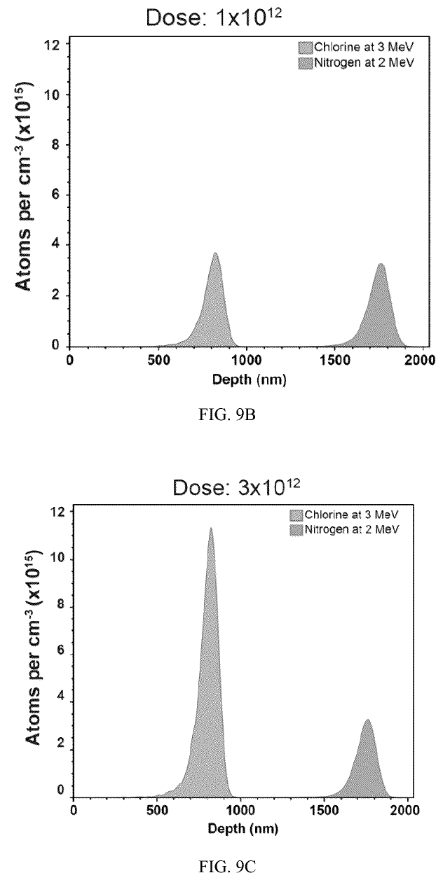

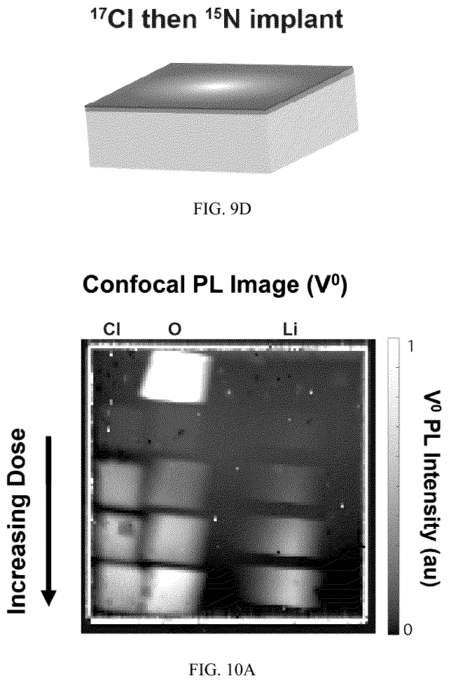

At an implant dose of 5×10¹¹ atoms/cm² and implant energy of 3 MeV, most of the chlorine atoms were distributed at a depth of between 500 nm and 1000 nm, with concentrations up to about 2×10¹⁵ chlorine atoms per cm³ (left hand part of the graph of FIG. 9A). SRIM simulations were carried out with ¹⁷Cl implantation, followed by ¹⁵N implantation.

As the implant dose increases to 1×10¹² atoms/cm², up to about 4×10¹⁵ chlorine atoms per cm³ were implanted (left hand part of the graph in FIG. 9B). At an implant dose of 3×10¹² atoms/cm², up to almost 12×10¹⁵ chlorine atoms per cm³ were implanted (left hand part of the graph in FIG. 9C). For SRIM simulations involving ¹⁷Cl and ¹⁵N implantation, ¹⁷Cl implantation was carried out first (top layer in FIG. 9D), followed by ¹⁵N (embedded layer in FIG. 9D).

### Example 2

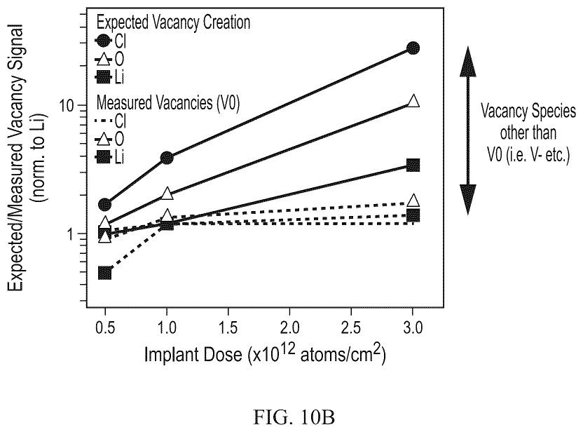

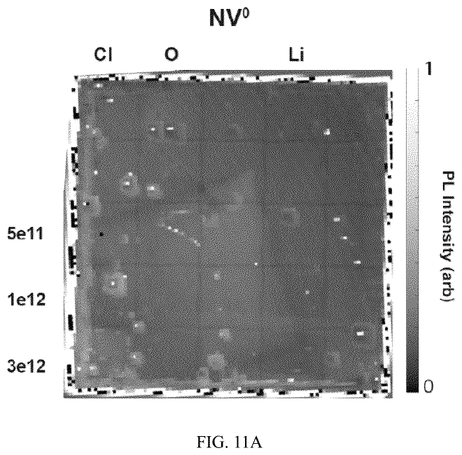

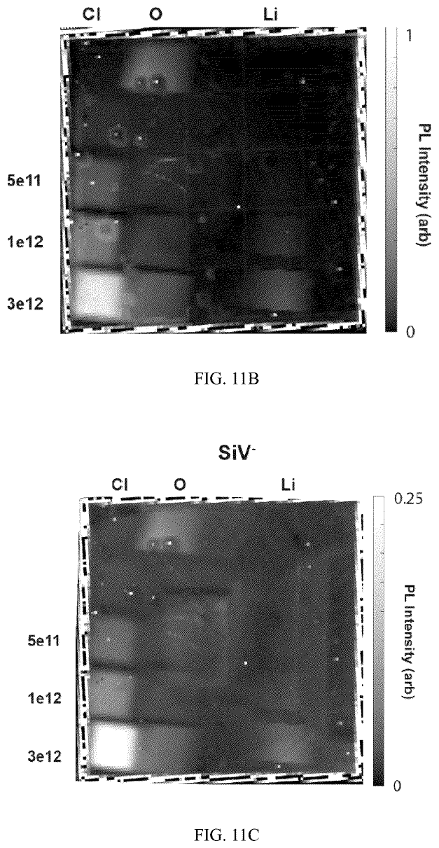

A Renishaw Qontor Raman Microscope was used to generate photoluminescence (PL) spectra (e.g., wavelength=532 nm) at 50 μm intervals across samples. NV⁰, NV⁻, SiV⁻, and V⁰ basis functions were established and fitted to the measured spectra for each implant square (FIGS. 10A-B and 11A-11C). FIG. 10A shows PL intensity before annealing, and FIGS. 11A-11C show PL intensity after annealing which activates vacancies such as NV⁰, NV⁻, and SiV⁻ species discussed next.

The graph of FIG. 10B shows the expected and measured vacancy signal (normalized to Li) as the Cl, O, or Li implant dose varies. As the implant dose increases from 0.5×10¹² atoms/cm² to 3.0×10¹² atoms/cm², the expected and measured vacancy signal increases for all dopants (Cl, O Li). Neutral vacancy species V⁰ contributes to the measured vacancy signal in FIG. 10B, while other species (such as V-species, NV-species etc.) in addition to V⁰ contribute to the expected vacancy signal.

FIG. 11A shows the amount of neutral vacancies (NV⁰s) as a function of dopant (Cl, O, or Li) and implant dose (5.0×10¹¹ atoms/cm², 1.0×10¹² atoms/cm², 3.0×10¹² atoms/cm²) after annealing. Out of the Cl, O, and Li dopants, the NV⁰ photoluminescence signal is the highest when Cl is used as a dopant. FIGS. 11B and 11C show annealing results after activation of NV⁻ and SiV⁻ species. As shown, the difference in NV⁻ and SiV⁻ photoluminescence signal increases when Cl is used as a dopant compared to the O or Li dopants. The difference in NV⁻ and SiV⁻ photoluminescence signal across dopant samples is more noticeable compared to the difference in NV⁰ photoluminescence signal. That is to say, annealing activates defects (vacancies), and the desired V-type defects (negative charged vacancies) are formed at higher implant doses and with Cl as the dopant.

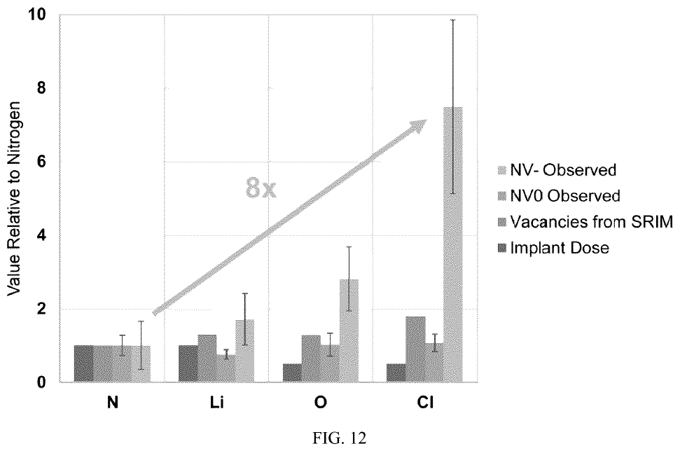

In FIG. 12, the mean and standard deviation of the photoluminescence intensities of a) nitrogen and lithium, b) nitrogen and oxygen, and c) nitrogen and chlorine implantation, versus nitrogen only without lithium, oxygen, or chlorine implantation, are shown. The FIG. 12 graph shows, the NV⁻ yield increases by almost 8 times when chlorine is used as a dopant rather than lithium or oxygen.

### Embodiments (in Non-Limiting Example)

1. A diamond comprising a crystal, wherein the crystal comprises
   a. a NV or SiV defect wherein a nitrogen atom or silicon atom replaces a carbon atom in the crystal;
   b. a V⁰ defect wherein a neutral vacancy replaces a carbon atom adjacent to the NV or SiV defect in the crystal;
   c. a halide atom; and
   d. a negatively charged vacancy defect V⁻;
   wherein the halide atom enhances properties of the diamond.
2. The diamond of Embodiment 1, wherein the crystal comprises a nitrogen atom.
3. The diamond of Embodiment 1, wherein the crystal comprises a silicon atom.
4. The diamond of any of Embodiments 1-3, wherein the halide atom is activated.
5. The diamond of any of Embodiments 1-4, wherein the crystal is photoluminescent.
6. The diamond of any of Embodiments 1-5, wherein the halide is fluorine, chlorine, bromine, or iodine.
7. The diamond of any of Embodiments 1-5, wherein the halide atom is chlorine.
8. The diamond of any of Embodiments 1-7, wherein the diamond is a quantum diamond and wherein the halide atom enhances defect-based qubits in the diamond.
9. The diamond of any of Embodiments 1-8, wherein the diamond is produced by a high-pressure high temperature (HPHT) or a chemical vapor deposition (PE-CVD) technique.
10. The diamond of any of Embodiments 1-9, wherein the diamond is produced by incorporating the halide by growing the diamond with a halide precursor flowing in the reactor chamber in gaseous form.
11. The diamond of any of Embodiments 1-9, wherein the diamond is produced by incorporating the halide into the diamond by ion implantation.
12. The diamond of any of Embodiments 1-11, wherein the diamond is produced by annealing.
13. The diamond of any of Embodiments 1-12, wherein the enhanced properties of the diamond are measured by a technique selected from photoluminescence (PL), coherence time measurements, crystallographic strain measurements, Fourier-Transform Infrared measurements (FTIR), Electron paramagnetic resonance (EPR), and Ultraviolet-Visible spectroscopy (UV-Vis).
14. The diamond of any of Embodiments 1-13, wherein the V″ pairs with a NV or SiV defect.
15. A quantum device comprising the diamond of any of Embodiments 1-14.
16. The quantum device of Embodiment 15, comprising a quantum computer or quantum sensor.

### REFERENCES

1. Assegid Mengistu Flatae, Stefano Lagomarsino, Florian Sledz, Navid Soltani, Shannon S. Nicley, Ken Haenen, Robert Rechenberg, Michael F. Becker, Silvio Sciortino, Nicla Gelli, Lorenzo Giuntini, Francesco Taccetti, Mario Agio, Silicon-vacancy color centers in phosphorus-doped diamond, Diamond and Related Materials, Volume 105, 2020, https://doi.org/10.1016/j.diamond.2020.107797.
2. Chloroform, Dichloromethane, and Other Halogenated Organic Compounds. University of Arizona, Safe Engineering. (n.d.). https://safe.engineering.asu.edu/chloroform-dichloromethane-and-other-halogenated-organic-compounds
3. Department of Labor, United States. Carbon Tetrachloride: Occupational Safety and Health Administration. (n.d.). https_www_osha_gov/chemicaldata/844
4. Department of Labor, United States. Phosphine: Occupational Safety and Health Administration. (n.d.). https_www_osha_gov/chemicaldata/667
5. Hefeng Cheng, Meicheng Wen, Xiangchao Ma, Yasutaka Kuwahara, Kohsuke Mori, Ying Dai, Baibiao Huang, and Hiromi Yamashita, Journal of the American Chemical Society 2016 138 (29), 9316-9324 DOI: 10.1021/jacs.6b05396
6. Toxic metal hydrides safety. Arizona State University. (n.d.). https_safe_engineering_asu_edu/wp-content/uploads/2011/12/Toxic-Metal-Hydrides-Safety.pdf
7. EPO Patent entitled “Boron doped CVD diamond” (Patent No. EP1780315B1)
8. Mass spectrometry and diamond from CCl4H2 gas mixtures (de Barros et al., 1997, C23C16/277)
9. US Published Application entitled “Boron-doped nanocrystalline diamond” (by Swain et al., 2004, Publication no. US20050110024A1).
10. US patent entitled “Method of growing boron doped single crystal diamond in a plasma reactor” (by Linares and Doering, 1999, U.S. Pat. No. 7,942,966B2).
11. Great Britain Patent Application entitled “Silicon doped diamond films” (by Miyata et al., 1989, Patent App. No. GB2228949A).
12. US patent entitled “Halogen-activated chemical vapor deposition of diamond” (by Hauge and Pan, 1995, U.S. Pat. No. 5,589,231) (expired).
13. Lühmann, T., John, R., Wunderlich, R. et al. Coulomb-driven single defect engineering for scalable qubits and spin sensors in diamond. Nat Commun 10, 4956 (2019). https_doi_org/10.1038/s41467-019-12556-0
14. Alsid, S. T., Barry, J. F., Pham, L. M., Schloss, J. M., O'Keeffe, M. F., Cappellaro, P. and Braje, D. A. Photoluminescence decomposition analysis: a technique to characterize N-V creation in diamond. Physical review applied, 12(4), p. 044003 (2019).

The teachings of all patents, published applications and references cited herein are incorporated by reference in their entirety.

While example embodiments have been particularly shown and described, it will be understood by those skilled in the art that various changes in form and details may be made therein without departing from the scope of the embodiments encompassed by the appended claims.

What is claimed is:

1. A diamond comprising:
a. a NV⁰ or SiV⁰ defect, wherein the NV⁰ or SiV⁰ defect comprises a nitrogen atom or silicon atom replacing a carbon atom in the diamond and a neutral vacancy replacing a carbon atom adjacent to the nitrogen atom or silicon atom in the diamond;
b. a NV⁻ or SiV⁻ defect, wherein the NV⁻ or SiV⁻ defect comprises a nitrogen atom or silicon atom replacing a carbon atom in the diamond and a negatively-charged vacancy replacing a carbon atom adjacent to the nitrogen atom or silicon atom in the diamond; and
c. a halide atom.

2. The diamond of claim 1, wherein the diamond comprises the NV⁰ defect, the NV⁻ defect, and the halide atom.

3. The diamond of claim 2, wherein the concentration of nitrogen atoms in the diamond is from about 1 ppm to about 10 ppm.

4. The diamond of claim 1, wherein the diamond is a diamond layer having a thickness of from about 1 μm to about 50 μm.

5. The diamond of claim 4, wherein the diamond is a diamond layer having a thickness of about 40 μm, and wherein the halide atom is at a depth of from about 0 μm to about 2 μm from a surface of the diamond.

6. The diamond of claim 1, wherein the halide atom is chlorine.

7. The diamond of claim 1, wherein the concentration of halide atoms in the diamond is from about 1×10¹⁵ atoms per cm³ to about 1×10¹⁷ atoms per cm³.

8. A quantum device comprising a diamond, the diamond comprising:
a. a NV⁰ or SiV⁰ defect, wherein the NV⁰ or SiV⁰ defect comprises a nitrogen atom or silicon atom replacing a carbon atom in the diamond and a neutral vacancy replacing a carbon atom adjacent to the nitrogen atom or silicon atom in the diamond;
b. a NV⁻ or SiV⁻ defect, wherein the NV⁻ or SiV⁻ defect comprises a nitrogen atom or silicon atom replacing a carbon atom in the diamond and a negatively-charged vacancy replacing a carbon atom adjacent to the nitrogen atom or silicon atom in the diamond; and
c. a halide atom.

9. The quantum device of claim 8, wherein the quantum device is a quantum computer or quantum sensor.

10. A method of forming a diamond layer, the method comprising:
a) growing a non-doped diamond layer having an as-grown growth face on a substrate, implanting a halide atom and an N or Si atom into the as-grown growth face of the non-doped diamond layer to produce a halide-doped diamond layer comprising a NV⁰ or SiV⁰ defect, and annealing the halide-doped diamond layer to form a NV⁻ or SiV⁻ defect from the NV⁰ or SiV⁰ defect;
b) growing an N-doped or Si-doped diamond layer having an as-grown growth face on a substrate using a dopant gas comprising a nitrogen or silicon source wherein the N-doped or Si-doped diamond layer comprises a NV⁰ or SiV⁰ defect, implanting a halide atom into the as-grown growth face of the N-doped or Si-doped diamond layer to produce a halide-doped diamond layer, and annealing the halide-doped diamond layer to form a NV⁻ or SiV⁻ defect from the NV⁰ or SiV⁰ defect; or
c) growing a halide-doped diamond layer having an as-grown growth face on a substrate using a dopant gas comprising a nitrogen or silicon source and a halide precursor wherein the halide-doped diamond layer comprises a NV⁰ or SiV⁰ defect and a halide atom, and annealing the halide-doped diamond layer to form a NV⁻ or SiV⁻ defect from the NV⁰ or SiV⁰ defect,
wherein the diamond layer comprises:
a. the NV⁰ or SiV⁰ defect, wherein the NV⁰ or SiV⁰ defect comprises a nitrogen atom or silicon atom replacing a carbon atom in the diamond and a neutral vacancy replacing a carbon atom adjacent to the nitrogen atom or silicon atom in the diamond;
b. the NV⁻ or SiV⁻ defect, wherein the NV⁻ or SiV⁻ defect comprises a nitrogen atom or silicon atom replacing a carbon atom in the diamond and a negatively-charged vacancy replacing a carbon atom adjacent to the nitrogen atom or silicon atom in the diamond; and
c. the halide atom.

11. The method of claim 10, the method further comprising removing the substrate from the halide-doped diamond layer.

12. The method of claim 10, wherein the annealing in a), b), or c) is performed using ultra-high vacuum annealing at a temperature of from about 800° C. to about 1200° C.

13. The method of claim 10, wherein the dopant gas in b) or c) comprises N₂, N₂O, Si(OC₂H₅)₄ or SiF₄.

14. The method of claim 10, wherein the implanting the halide atom in a) or b) comprises using an implant dose of from about 1×10¹⁰ atoms/cm² to about 1×10¹⁵ atoms/cm².

15. The method of claim 10, wherein the implanting the halide atom in a) or b) comprises using an implant energy of from about 1 MeV to about 5 MeV.

16. The method of claim 10, wherein the halide precursor is titanium (IV) chloride, carbon tetrabromide, vanadium (V) trichloride oxide, boron bromide, 3-aminopropyltriethoxysilane, or hafnium tetrachloride.

17. The method of claim 10, wherein the halide atom is chlorine.

18. The method of claim 10, wherein the growing in a), b), or c) comprises using a high-pressure high temperature (HPHT) or a chemical vapor deposition (CVD) technique.

19. The method of claim 18, wherein the chemical vapor deposition technique is plasma enhanced chemical vapor deposition (PE-CVD).

20. The method of claim 19, wherein the plasma enhanced chemical vapor deposition (PE-CVD) comprises injecting methane and hydrogen gas into a chamber to reach a pressure of about 100 torr to about 200 torr.
